(19) United States
(12) Patent Application Publication
(10) Pub. No.: US 2007/0205507 A1
(43) Pub. Date: Sep. 6, 2007

(54) Carbon and nitrogen based cap materials for metal hard mask scheme

(76) Inventors: Hui-Lin Chang, Hsin-Chu (TW); Yung-Cheng Lu, Taipei (TW); Tien-I Bao, Hsin-Chu (TW)

Correspondence Address: SLATER & MATSIL, L.L.P., 17950 PRESTON ROAD, SUITE 1000, DALLAS, TX, 75252, US

(21) Appl. No.: 11/365,975

(22) Filed: Mar. 1, 2006

(51) Int. Cl. H01L 23/48

(52) U.S. Cl. 257/734

(57) ABSTRACT

A semiconductor structure having a novel cap layer on a low-k dielectric layer and a method for forming the same are provided. The cap layer preferably includes a material selected from the group consisting essentially of CNₓ, SiCN, SiCO, SiC, and combinations thereof. The semiconductor structure further includes a via in the low-k dielectric layer, and a metal line in the low-k dielectric layer and on the via. An etch stop layer is preferably formed on the cap layer.

### TECHNICAL FIELD

This invention relates generally to semiconductor device interconnections, and more particularly to materials for capping low-k dielectrics.

### BACKGROUND

High-density integrated circuits, such as very large scale integration (VLSI) circuits, are typically formed with multiple metal interconnects to serve as three-dimensional wiring line structures. The purpose of multiple interconnects is to properly link densely packed devices together. With increasing levels of integration, a parasitic capacitance effect between the metal interconnects, which leads to RC delay and cross talk, increases correspondingly. In order to reduce the parasitic capacitance and increase the conduction speed between the metal interconnections, low-k dielectric materials are commonly employed to form inter-layer dielectric (ILD) layers and inter-metal dielectric (IMD) layers.

One of the commonly used schemes for forming low-k related structures is a metal hard mask (MHM) scheme, wherein a metallic hard mask is formed to protect a low-k dielectric layer from chemical mechanical polish (CMP). Typically, a cap layer is formed on the low-k dielectric layer followed by a metal hard mask layer. The cap layer is typically formed of oxide-based material such as tetra ethyl ortho silicate (TEOS). The metal hard mask layer and the cap layer are then patterned, preferably using photo resists as masks. The patterns are transferred to the underlying low-k dielectric layer to form interconnections, and the process typically includes forming openings in the low-k dielectric layer, filling the openings with a conductive material, and performing a CMP to planarize the surface. The metal hard mask layer is then removed.

The conventional MHM scheme suffers drawbacks, however. Oxide based cap materials such as TEOS typically have inferior optical characteristics, for example, low extinction coefficients (k), so that they can be easily penetrated by light from an optical projection system, making pattern control difficult. The selectivity between the oxide based cap material and the metal hard mask as well as copper during the chemical mechanical polish (CMP) is not high enough, and damage may occur to the cap layer during the CMP process. Additionally, oxide based cap materials typically have relatively low resistance to the chemicals used for etching the metal hard mask, and pronounced line end voids may form. This causes the cap layer to have rough edges, and may lead to undesired side effects.

Therefore, there is the need for novel cap layer materials overcoming the above-discussed shortcomings.

### SUMMARY OF THE INVENTION

The preferred embodiment of the present invention provides a semiconductor structure, particularly a material, for interconnections and a method for forming the same.

In accordance with one aspect of the present invention, the semiconductor structure includes a cap layer on a low-k dielectric layer. The cap layer preferably includes a material selected from the group consisting essentially of CNₓ, SiCN, SiCO, SiC, and combinations thereof. The semiconductor structure further includes a via and an overlying metal line in the low-k dielectric layer, wherein the metal line is physically connected to the via. An etch stop layer is preferably formed on the cap layer.

In accordance with another aspect of the present invention, a method for forming the preferred embodiment of the present invention includes forming a cap layer on a low-k dielectric layer wherein the cap layer comprises a material selected from the group consisting essentially of CNₓ, SiCN, SiCO, SiC, and combinations thereof, forming a metal hard mask over the cap layer, forming and patterning a first photo resist over the metal hard mask, etching the metal hard mask to form a first opening, removing the first photo resist, forming and patterning a second photo resist, forming a trench opening and a via opening, filling the trench opening and the via opening with a conductive material, and removing excessive conductive material. The remaining conductive material forms a via and a conductive line. The metal hard mask is then removed. The method further includes forming an etch stop layer on the cap layer.

The advantageous features of the preferred embodiments of the present invention include better pattern control due to optical characteristics of the cap layer, greater mechanical strength in the semiconductor structure, and better adhesion between the cap layer and the overlying etch stop layer as well as the underlying low-k dielectric layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 9 are cross-sectional views of intermediate stages in the manufacture of a preferred embodiment of the present invention.

### DETAILED DESCRIPTION OF ILLUSTRATIVE EMBODIMENTS

The making and using of the presently embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

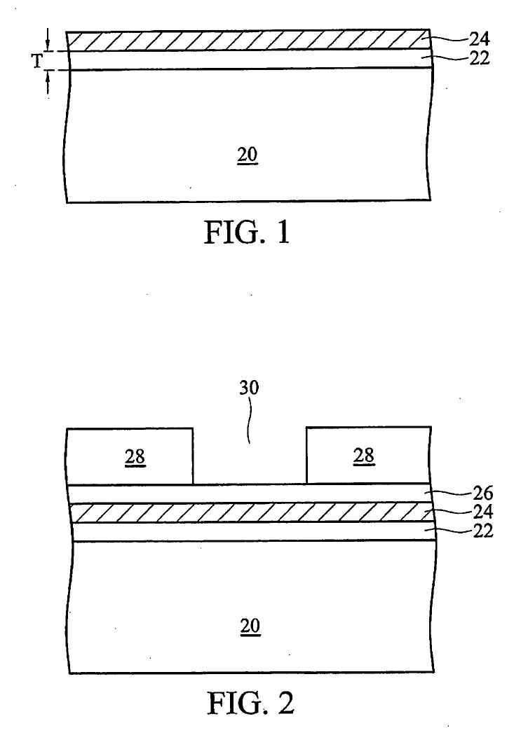

The embodiments of the present invention are illustrated in FIGS. 1 through 9, wherein like reference numbers are used to designate like elements throughout the various views and illustrative embodiments of the present invention.

FIG. 1 illustrates the formation of a cap layer 22 and a metal hard mask 24 on a low-k dielectric layer 20, which provides insulation between underlying features (not shown) and metal lines that will be formed subsequently. Low-k dielectric layer 20 has a low dielectric constant value (k), preferably lower than about 3.5, and more preferably lower about than 2.5, hence sometimes referred to as an extreme low-k dielectric material. Low-k dielectric layer 20 may comprise carbon-doped silicon oxides, fluorine-doped silicon oxides, organic low-k materials, porous low-k materials, and the like. Deposition methods include spin on, chemical vapor deposition (CVD), plasma enhanced CVD (PECVD), low pressure CVD (LPCVD), and other known deposition techniques.

A cap layer 22 is formed on the low-k dielectric layer 20. Cap layer 22 preferably comprises carbon and/or nitrogen based materials such as CNₓ, SiCN, SiCO, SiC, and the like. The thickness T of the cap layer 22 is between about 100 Å and 1500 Å.

Due to the use of a low-k dielectric material for layer 20, parasitic capacitance caused by cap layer 22 becomes more significant. Therefore, cap layer 22 preferably has a low dielectric constant (k value) of less than about 4.5, and more preferably less than about 3.0. For example, CNₓ has a k value of less than about 2, SiCN has a k value of between about 3.0 and 5.0, SiCO has a k value of between about 3.0 and 4.5 and SiC has a k value of between 3.0 and 4.5. The k value of each of the materials is also related to the formation processes. With a properly selected material (or combination of materials) and formation processes, a desired k value can be achieved.

Carbon and nitrogen based materials, such as CNₓ, SiCN, SiCO, SiC have high extinction coefficients, thus low penetration rates for light used by lithography processes. Lithography pattern control is thus easier. Particularly, the cap layer 22 is hard for light in a wide range of wavelengths to penetrate. Therefore, there is more room to select an imaging light with a desired wavelength, for example, a light with a shorter wavelength for small-scale circuit formation.

Additionally, the determination of an optimum thickness T of the cap layer 22 needs to take into account various factors such as the reflection from other layers. Therefore, typically, the thickness T of the cap layer 22 cannot be as thin as desired if oxide based materials are used. However, with a low penetration rate for light, the thickness of cap layer 22 can be reduced to a desired thickness with less concern for optical effects.

Cap layer 22 may be formed by commonly used methods, such as chemical vapor deposition (CVD) and physical vapor deposition (PVD). However, other commonly used methods such as atomic layer deposition (ALD), may also be used. For CVD methods, the process gases include carbon and hydrogen containing gases, such as N₂, NH₃, 3MS ((CH₃)₃SiH, also known as trimethylsilane), and 4MS (Si(CH₃)₄, also known as tetramethylsilane). For PVD methods, the targets include graphite, azaadenine, adnine, and melamine, and the deposition is performed in a chamber containing N₂ and NH₃.

Exemplary formation processes for forming cap layer 22 comprising different materials are shown below. In an exemplary process forming a SiC-containing cap layer 22, plasma enhanced CVD is used, and the formation settings may include:

| | |
|---|---|
| Precursor: | 4MS |
| Flow rate: | ˜500 to about 2500 sccm |
| Chamber pressure: | ˜1 mtorr to about 20 torr |
| Temperature: | ˜100° C. to 500° C. |

If SiOC is preferred, process gases may further include CO₂ to supply oxygen. Other gases such as O₂ and octamethylcyclotetrasiloxane (OMCTS) can also be used.

In another exemplary process forming a SiCN-containing cap layer 22, the forming conditions include:

| | |
|---|---|
| Precursor: | 3MS or 4MS, NH₃ and N₂ |
| Flow rate: | ˜500 to about 2500 sccm |
| Chamber pressure: | ˜1 mtorr to about 20 torr |
| Temperature: | ˜100° C. to 500° C. |

As is known in the art, the dielectric constant (k value) and extinction coefficient value of the cap layer 22 may be affected by the formation process, and may be adjusted by changing the forming conditions such as the partial pressures of process gases. Since a high extinction coefficient (k) value is preferred, cap layer 22 may comprise a combination of CNₓ, SiCN, SiCO, and SiC, so that the extinction coefficient value is higher than about 0.1. Formation processes may be adjusted accordingly.

Low-k dielectric layer 20 typically has a tensile stress, and tends to crack or peel due to internal stress release. Cap layer 22 formed of CNₓ, SiCN, SiCO, SiC may provide a high compressive stress to the underlying low-k dielectric layer 20, and the compressive stress is preferably greater than about −2.0 E9 dy/cm², which is greater than a typical stress provided by an oxide-based cap layer. High compressive stress in cap layer 22 compensates for and/or alleviates the tensile stress of the low-k dielectric 20 to avoid film cracking and peeling induced by internal stress release. The mechanical strength of the low-k dielectric layer 20, hence the mechanical strength of the resulting semiconductor structure, is thus improved.

A metal hard mask (MHM) 24 is formed on cap layer 22. MHM 24 is formed of metallic materials, such as Ti, TiN, Ta, TaN, Al, and the like, although in a non metal hard mask scheme, non-metallic materials, such as SiO₂, SiC, SiN, SiON, may be used.

Referring to FIG. 2, an anti-reflective coating (ARC) 26 is formed over MHM 24. ARC 26 is also referred to as a bottom anti-reflective coating (BARC) 26 since it is formed under a subsequently formed photo resist. Alternatively, a top anti-reflective coating (TARC) may be formed on top of the subsequently formed photo resist. BARC 26 absorbs light and provides ultimate critical dimension control. BARC 26 can be applied by spin on technique or be deposited in a gas chamber.

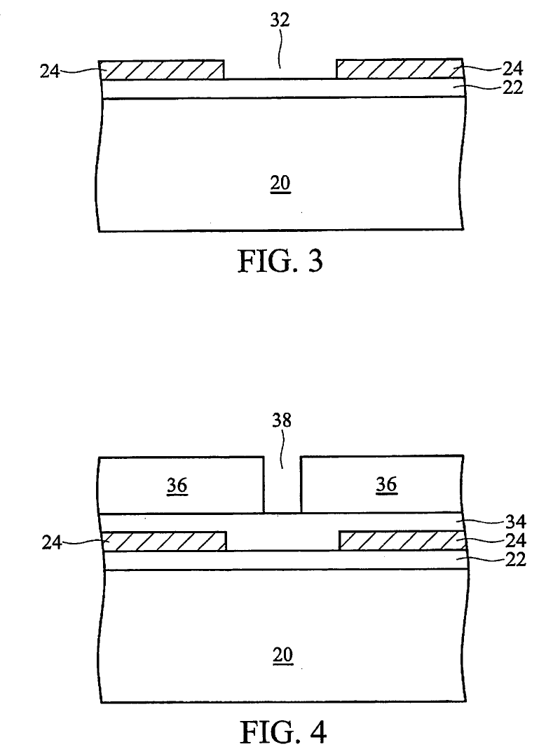

A photo resist 28 is then formed and patterned, and an opening 30 is formed therein, exposing the underlying BARC 26. Next, an opening 32 is formed through MHM 24, as shown in FIG. 3, by etching the BARC 26 and the MHM 24 through the opening 30. Photo resist 28 and BARC 26 are then removed. In subsequent dual damascene processes for forming a via and a metal line in low-k dielectric layer 20, opening 32 is used to define a trench pattern for the metal line.

Referring to FIG. 4, a photo resist 36, and a BARC 34, are formed. The photo resist 36 is patterned, forming an opening 38, which defines a pattern for the via subsequently formed in low-k dielectric layer 20.

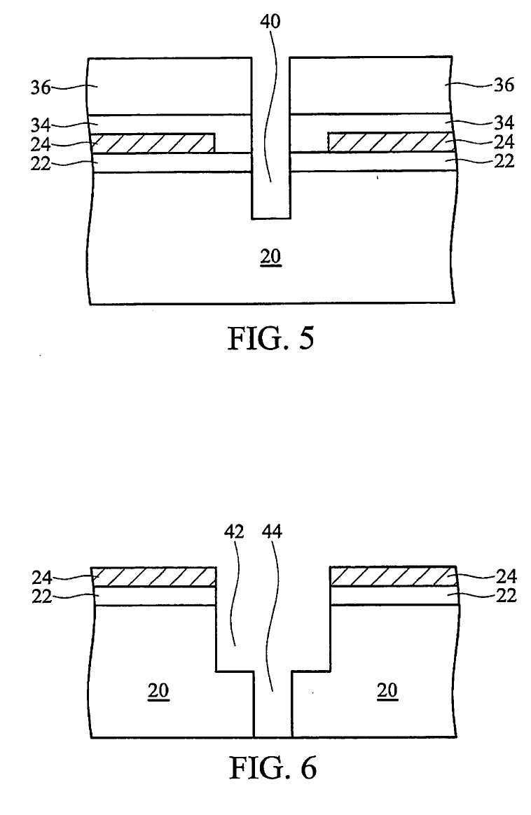

A via partial etch is then performed, as shown in FIG. 5. Using photo resist 36 as a mask, underlying layers including BARC 34, MHM 24, cap layer 22 and a portion of the low-k dielectric layer 20 are removed, forming an opening 40 in the low-k dielectric layer 20. The etching process is controlled so that the depth of the opening 40 is less than a desired thickness of the subsequently formed metal line.

FIG. 6 illustrates the formation of a trench opening 42 and via opening 44, preferably by etching. As is known in the art, appropriate chemicals are preferably used combined with process control so that the formation of trench opening 42 and via opening 44 can be performed at a more controllable rate. During the etching process, opening 40 extends downward until the low-k dielectric layer 20 is etched through, forming the via opening 44. At the same time, photo resist 36 and BARC 34 are etched thinner over time, and eventually, respective portions of photo resist 36 and BARC 34 on MHM 24 are removed, exposing underlying MHM 24. MHM 24 then acts as a new mask, and the low-k dielectric layer 20 unprotected by the MHM 24 is etched. Since MHM 24 defines the pattern of the trench for a metal line, trench opening 42 is formed. With careful control of the etching process, trench opening 42 will reach a desired depth when via opening 44 reaches the bottom of the low-k dielectric layer 20.

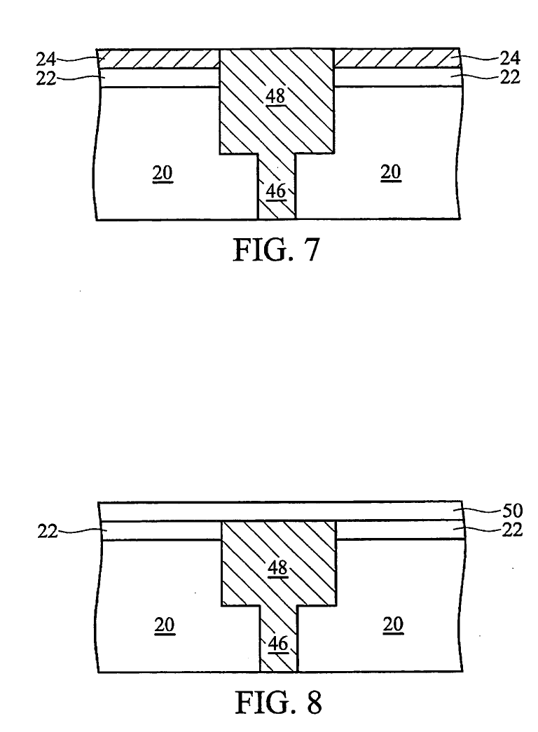

FIG. 7 illustrates the formation of a via 46 and a metal line 48. As is known in the art, a conductive material, preferably a metallic material such as copper, tungsten, metal alloys, metal silicide, and metal nitrides, may be filled into the via openings 44 and trench opening 42. The excessive material is then removed by using chemical mechanical polish (CMP), leaving metal line 48 and via 46. MHM 24 is used as a stopper during the CMP.

Since low-k dielectric layer 20 and cap layer 22 are etched using a same MHM 24 as the mask, substantially no cap layer 22 remains on metal line 48. Conversely, a subsequently formed etch stop layer will likely have at least a portion on the metal line 48.

MHM 24 is then removed by etching. Cap layer 22 remains on low-k dielectric layer 20, as shown in FIG. 8. If the low-k dielectric layer 20 is not the highest inter-metal dielectric layer, an additional etch stop layer (ESL) 50 may be formed over cap layer 22. ESL 50 comprises SiN, SiC or other commonly used materials, which have different etching characteristics from the underlying cap layer 22, so that when ESL 50 is etched, cap layer 22 remains substantially undamaged.

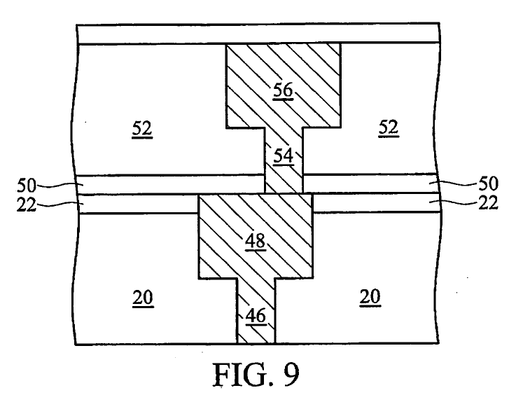

FIG. 9 illustrates the formation of another low-k dielectric (or IMD) layer 52. Vias and metal lines, such as via 54 and metal line 56, can be formed in low-k dielectric layer 52 and be connected to the conductive features in the low-k dielectric layer 20. Vias and metal lines in the low-k dielectric layer 52 can be formed using similar process steps and materials used for forming via 46 and metal line 48. The formation processes are thus not repeated herein.

Although in the previously discussed embodiments, the via opening and trench opening are formed in a same etching step, one skilled in the art will realize that other known dual damascene processes can also be used. For example, the via opening and trench opening may be etched separately using separate photo resists. Low-k dielectric layer 20 can also include two sub layers having different etching characteristics, so that the depth of the trench opening can easily be controlled. Additionally, the cap layer 22 is not limited to a metal hard mask scheme.

The embodiments of the present invention have several advantageous features besides what are discussed in previous paragraphs. Firstly, cap layer 22 formed of CNₓ, SiCN, SiCO, SiC is chemically inert and has high thermal stability and a high electrical breakdown field, thus the resistance to thermal cycles and applied electrical stress is improved. Secondly, cap layer 22 formed of CNₓ, SiCN, SiCO, SiC has better adhesion to the underlying low-k dielectric layer and the overlying ESL than an oxide-based cap layer. Mechanical strength of the resulting semiconductor structure is thus improved. Thirdly, the formation processes of the preferred embodiments of the present invention are fully compatible with current integration circuit fabrication processes, and can be made by existing tools and methods, so that there is no extra cost involved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a low-k dielectric layer;
a cap layer on the low-k dielectric layer, wherein the cap layer comprises a material selected from the group consisting essentially of CNₓ, SiCN, SiCO, SiC, and combinations thereof;
a via in the low-k dielectric layer; and
a metal line in the low-k dielectric layer and overlying the via, the metal line being physically connected to the via.

2. The semiconductor structure of claim 1 further comprising an etch stop layer on the cap layer.

3. The semiconductor structure of claim 1, wherein the cap layer is substantially free from a region overlying the metal line.

4. The semiconductor structure of claim 1, wherein the cap layer has a thickness of between about 100 Å and about 1000 Å.

5. The semiconductor structure of claim 1, wherein the cap layer has a compressive stress of greater than about 2.0 E9 dy/cm².

6. The semiconductor structure of claim 1, wherein the cap layer has an extinction coefficient (k) value of greater than about 0.1.

7. The semiconductor structure of claim 1, wherein the low-k dielectric layer has a dielectric constant of less than about 2.5.

8. A semiconductor structure comprising:
a low-k dielectric layer;
a cap layer on the low-k dielectric layer, wherein the cap layer comprises a material selected from the group consisting essentially of CNₓ, SiCN, SiCO and combinations thereof;
an etch stop layer on the cap layer;
a via in the low-k dielectric layer; and
a metal line in the low-k dielectric layer and overlying the via, the metal line being physically connected to the via, wherein the cap layer is substantially free from a region overlying the metal line.

9. The semiconductor structure of claim 8, wherein the cap layer has a thickness of between about 100 Å and about 1000 Å.

10. The semiconductor structure of claim 8, wherein the cap layer has a compressive stress of greater than about 2.0 E9 dy/cm².

11. The semiconductor structure of claim 8, wherein the cap layer has an extinction coefficient (k) value of greater than about 0.1.

12. The semiconductor structure of claim 8 further comprising an additional low-k dielectric layer on the etch stop layer, wherein an additional via and an additional metal line are in the additional low-k dielectric layer.

13. The semiconductor structure of claim 8, wherein the low-k dielectric layer has a dielectric constant of less than about 2.5.

14. A method for forming a semiconductor structure, the method comprising:
forming a low-k dielectric layer;
forming a cap layer on the low-k dielectric layer, wherein the cap layer comprises a material selected from the group consisting essentially of CNₓ, SiCN, SiCO, SiC, and combinations thereof;
forming a metal hard mask over the cap layer;
forming and patterning a first photo resist over the metal hard mask;
etching the metal hard mask to form a first opening;
removing the first photo resist;
forming and patterning a second photo resist;
forming a trench opening and a via opening;
filling the trench opening and the via opening with a conductive material; and
planarizing to form a metal line and a via.

15. The method of claim 14 further comprising forming a first bottom anti-reflecting coating (BARC) underlying the first photo resist and a second BARC underlying the second photo resist.

16. The method of claim 14, wherein the step of forming the trench opening and the via opening further comprises a via partial etching.

17. The method of claim 14, wherein the cap layer is formed by a physical vapor deposition (PVD) method using a target comprising a material selected from the group consisting essentially of graphite, azaadenine, adnine, melamine and combinations thereof, and wherein process gases comprise N₂, NH₃, and combinations thereof.

18. The method of claim 14, wherein the cap layer is formed by a chemical vapor deposition (CVD) method, and wherein process gases comprise N₂, NH₃, 3MS, 4MS, and combinations thereof.

19. The method of claim 14, wherein the step of forming the cap layer is performed at a temperature of between about 100° C. and about 500° C.

20. The method of claim 14, wherein the step of forming the cap layer is performed in a chamber having a pressure of between 1 mtorr and about 20 torr.
